(19) United States
(12) Patent Application Publication
(10) Pub. No.: US 2022/0154335 A1
(43) Pub. Date: May 19, 2022

(54) AEROSPACE COMPONENTS HAVING PROTECTIVE COATINGS AND METHODS FOR PREPARING THE SAME

(71) Applicant: Applied Materials, Inc., Santa Clara, CA (US)

(72) Inventors: Sukti CHATTERJEE, San Jose, CA (US); David Alexander BRITZ, San Jose, CA (US); Lance A. SCUDDER, Sunnyvale, CA (US)

(21) Appl. No.: 16/951,837

(22) Filed: Nov. 18, 2020

(51) Int. Cl. C23C 16/455; C23C 16/40; B64C 1/40

(52) U.S. Cl. CPC C23C 16/45529; C23C 16/45553; B64C 1/40; C23C 16/403; C23C 16/405

(57) ABSTRACT

Embodiments of the present disclosure generally relate to protective coatings on aerospace components and methods for depositing the protective coatings. In one or more embodiments, an aerospace component containing a protective coating is provided and contains a superalloy substrate and a bond coating disposed on the superalloy substrate. The protective coating also contains a thermal barrier coating containing yttria-stabilized zirconia disposed on the bond coating, an oxide coating disposed on the thermal barrier coating, and an optional capping layer disposed on the oxide coating. The oxide coating contains a film stack containing two or more pairs of a first film and a second film, where the first film contains a first metal oxide and the second film contains a second metal oxide, and the first metal oxide has a different composition than the second metal oxide. The capping layer contains aluminum oxide, calcium oxide, magnesium oxide, or any combination thereof.

### BACKGROUND

### Field

Embodiments of the present disclosure generally relate to deposition processes, and in particular to vapor deposition processes for depositing films on aerospace components.

### Description of the Related Art

Turbine engines typically have components which corrode or degrade over time due to being exposed to hot gases and/or reactive chemicals (e.g., acids, bases, or salts). Such turbine components are often protected by a thermal and/or chemical barrier coating. The current coatings used on airfoils exposed to the hot gases of combustion in gas turbine engines serve as both environmental protection and as protective coatings with various metal alloy coatings. The protective coatings are applied over substrate materials, typically nickel-based superalloys, to provide protection against oxidation and corrosion attack.

However, the protective coatings are susceptible to corrosion due to glassy melts containing calcium-magnesium alumino-silicates (CMAS). The glassy melts are formed from silica particles (e.g., sand or dust) sucked into an intake and adhered to the hot surfaces of turbine components (e.g., turbine blades, combustors, airfoils, etc.). The glassy melts often penetrate the protective coating by a capillary effect and/or chemically react with the protective coating. Thereafter, the underlying superalloy is corroded or otherwise attacked by the glassy melts which leads to turbine damage and eventually failure.

Therefore, improved protective coatings and methods for depositing the protective coatings are needed for turbine components and other aerospace components.

### SUMMARY

Embodiments of the present disclosure generally relate to protective coatings on aerospace components and methods for depositing the protective coatings. In one or more embodiments, an aerospace component containing a protective coating is provided and contains a nickel-based superalloy substrate and a bond coating disposed on the nickel-based superalloy substrate, where the bond coating contains an alloy containing chromium and aluminum. The protective coating also contains a thermal barrier coating containing yttria-stabilized zirconia disposed on the bond coating and an oxide coating disposed on the thermal barrier coating.

In some embodiments, an aerospace component containing a protective coating is provided and contains a nickel-based superalloy substrate and a bond coating disposed on the nickel-based superalloy substrate, where the bond coating contains an alloy containing chromium, aluminum, a first element selected from nickel or cobalt, and a second element selected from hafnium, tungsten, zirconium, yttrium, or lanthanide. The protective coating also contains a thermal barrier coating containing yttria-stabilized zirconia disposed on the bond coating, an oxide coating disposed on the thermal barrier coating, and a capping layer disposed on the oxide coating. The oxide coating contains a film stack containing two or more pairs of a first film and a second film, where the first film contains a first metal oxide and the second film contains a second metal oxide, and the first metal oxide has a different composition than the second metal oxide. The capping layer contains aluminum oxide, calcium oxide, magnesium oxide, or any combination thereof.

In other embodiments, a method of forming a protective coating on an aerospace component is provided and includes depositing a bond coating on a nickel-based superalloy substrate, depositing a thermal barrier coating containing yttria-stabilized zirconia on the bond coating, and forming an oxide coating on the thermal barrier coating by depositing a film stack containing a first film and a second film by atomic layer deposition (ALD). The bond coating includes an alloy containing chromium, aluminum, a first element selected from nickel or cobalt, and a second element selected from hafnium, tungsten, zirconium, yttrium, or lanthanide. The first film contains a first metal oxide and the second film contains a second metal oxide, and the first metal oxide has a different composition than the second metal oxide.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic cross-sectional view of a protective aerospace component containing a protective coating, according to one or more embodiments described and discussed herein.

FIG. 2 is a schematic cross-sectional view of a protective aerospace component containing another protective coating, according to one or more embodiments described and discussed herein.

FIG. 3 is a schematic cross-sectional view of a protective aerospace component containing another protective coating, according to one or more embodiments described and discussed herein.

To facilitate understanding, identical reference numerals have been used, where possible, to designate identical elements that are common to the Figures. It is contemplated that elements and features of one or more embodiments may be beneficially incorporated in other embodiments.

### DETAILED DESCRIPTION

Embodiments of the present disclosure generally relate to protective coatings, such as single layers, multi-layer films, nanolaminate film stacks, and/or coalesced films, disposed on an aerospace components and methods for depositing the protective coatings. The protective coatings can be deposited or otherwise formed on interior surfaces and/or exterior surfaces of the aerospace components. The protective coatings described and discussed herein reduce or eliminate corrosion and/or oxidation caused by glassy melts containing calcium-magnesium alumino-silicates (CMAS), high temperature oxidation, and other sources of deterioration and/or destruction of the protective coating and underlying superalloy substrate component.

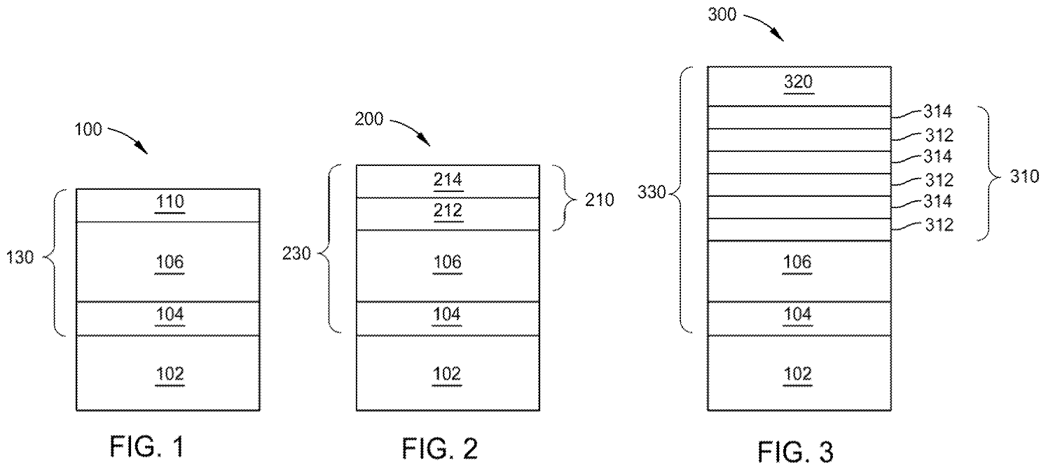

FIG. 1 is a schematic cross-sectional view of a protected aerospace component 100 containing a protective coating 130 disposed on a substrate 102, according to one or more embodiments described and discussed herein. The protective coating 130 contains a bond coating 104 disposed on the substrate 102, a thermal barrier coating (TBC) 106 disposed on the bond coating 104, and an oxide coating 110 disposed on the thermal barrier coating 106.

The substrate 102 can be a nickel-based superalloy substrate, a cobalt-based superalloy substrate, a stainless steel substrate, or another type of substrate. The substrate 102 can be or include an aerospace component, part, portion, or surface thereof, rotary equipment, or any other component or part that can benefit from the protective coating 130. For example, the substrate 102 can be or include an aerospace component or other rotary equipment component, such as a turbine blade, a turbine disk, a turbine vane, a turbine wheel, a fan blade, a compressor wheel, an impeller, a fuel nozzle, a fuel line, a valve, a heat exchanger, or an internal cooling channel, as well as other components or parts. The aerospace component, the substrate 102, and any surface thereof including one or more outer or exterior surfaces and/or one or more inner or interior surfaces can be made of, contain, or otherwise include one or more metals, such as nickel, aluminum, chromium, iron, steel, stainless steel, titanium, hafnium, one or more nickel superalloys, one or more Inconel alloys, one or more Hastelloy alloys, alloys thereof, or any combination thereof.

In one or more embodiments, the bond coating 104 has an alloy containing chromium, aluminum, and one, two, or more additional elements. For example, the bond coating 104 can have an alloy which contains chromium, aluminum, a first element selected from nickel or cobalt, and a second element selected from hafnium, tungsten, zirconium, yttrium, or lanthanide. In some embodiments, the alloy of the bond coating 104 can have the formula MCrAlX, where M is nickel or cobalt and X is hafnium, tungsten, zirconium, yttrium, lanthanide, or any combination thereof. For example, the bond coating 104 can be or include one or more alloys of NiCrAlY, NiCrAlHf, NiCrAlZr, NiCoCrAlY, NiCoCrAlYTa, or combinations thereof. The alloy of the bond coating 104 can include nickel or cobalt in an amount of about 60 wt %, about 62 wt %, or about 65 wt % to about 66 wt %, about 70 wt %, about 75 wt %, about 78 wt %, or about 79 wt %. The alloy of the bond coating 104 can include about 15 wt %, about 18 wt %, or about 20 wt % to about 21 wt %, about 22 wt %, or about 25 wt %. The alloy of the bond coating 104 can include aluminum in an amount of about 6 wt %, about 7 wt %, about 8 wt %, or about 9 wt % to about 10 wt %, about 11 wt %, about 12 wt %, or about 13 wt %. The alloy of the bond coating 104 can include each of hafnium, tungsten, zirconium, yttrium, and/or lanthanide in an amount of about 0.001 wt %, about 0.01 wt %, or about 0.1 wt % to about 0.2 wt %, about 0.5 wt %, about 0.8 wt %, about 0.9 wt %, about 0.95 wt %, or less than 1 wt %. In one or more examples, nickel or cobalt in an amount of about 60 wt % to about 79 wt %, the chromium in an amount of about 15 wt % to about 25 wt %, aluminum in an amount of about 6 wt % to about 13 wt %, each of hafnium, tungsten, zirconium, yttrium, and/or lanthanide in an amount of about 0.001 wt % to less than 1 wt %, such as about 0.95 wt % or less. In other embodiments, the bond coating 104 can be or include one or more alloys of SiAl, PtAl, NiAl, modified NiAl including Pt, Rh, Pd, or combinations thereof. In some embodiments, the bond coating 104 can independently include Ni, Co, Cr, Al, Pt, Rh, Pd, Re, Hf, W, Zr, Ta, rare earth elements (e.g., Y or La), or combinations thereof.

The bond coating 104 can be deposited, produced, or otherwise formed by one or more vapor deposition processes, such as atomic layer deposition (ALD), plasma-enhanced ALD (PE-ALD), chemical vapor deposition (CVD), plasma-enhanced CVD (PE-CVD), physical vapor deposition (PVD), or combinations thereof. The bond coating 104 can also be formed using low pressure plasma spray, cathodic arc, electron-beam PVD (EBPVD), electroplating with a platinum group metal, aluminizing, or combinations thereof. In some embodiments, the bond coating 104 can be formed using high velocity oxy-fuel (HVOF), air plasma spray (APS), or combinations thereof. The bond coating 104 can optionally be annealed to enhance adhesion to the substrate 102 and to enhance inter-diffusion. For example, the bond coating 104 disposed on the substrate 102 can be heated to a temperature of about 500° C. to about 1,200° C. for about 1 minute to about 90 minutes during an annealing process.

The bond coating 104 has a thickness of about 50 nm, about 100 nm, about 200 nm, about 500 nm, about 800 nm, or about 1 μm to about 5 μm, about 10 μm, about 20 μm, about 30 μm, about 50 μm, about 80 μm, or about 100 μm. For example, the bond coating 104 has a thickness of about 50 nm to about 100 μm, about 100 nm to about 50 μm, about 100 nm to about 25 μm, about 100 nm to about 10 μm, about 100 nm to about 5 μm, about 100 nm to about 1 μm, about 500 nm to about 50 μm, about 500 nm to about 25 μm, about 500 nm to about 10 μm, about 500 nm to about 5 μm, about 500 nm to about 1 μm, about 1 μm to about 50 μm, about 1 μm to about 25 μm, about 1 μm to about 10 μm, or about 1 μm to about 5 μm.

In one or more embodiments, the thermal barrier coating 106 contains yttria-stabilized zirconia (YSZ). The thermal barrier coating 106 and/or the yttria-stabilized zirconia contains about 5 molar percent (mol %), about 6 mol %, or about 7 mol % to about 8 mol %, about 9 mol %, or about 10 mol % of yttria. For example, the thermal barrier coating 106 and/or the yttria-stabilized zirconia contains about 5 mol % to about 10 mol %, about 6 mol % to about 10 mol %, about 7 mol % to about 10 mol %, about 8 mol % to about 10 mol %, about 9 mol % to about 10 mol %, about 5 mol % to about 8 mol %, about 6 mol % to about 8 mol %, or about 7 mol % to about 8 mol % of yttria.

The thermal barrier coating 106 and/or the yttria-stabilized zirconia contains about 90 mol %, about 91 mol %, or about 92 mol % to about 93 mol %, about 94 mol %, or about 95 mol % of zirconia. For example, the thermal barrier coating 106 and/or the yttria-stabilized zirconia contains about 90 mol % to about 95 mol %, about 91 mol % to about 95 mol %, about 92 mol % to about 95 mol %, about 93 mol % to about 95 mol %, about 90 mol % to about 93 mol %, about 91 mol % to about 93 mol %, or about 92 mol % to about 93 mol % of zirconia.

In one or more examples, the thermal barrier coating 106 and/or the yttria-stabilized zirconia contains about 5 mol % to about 10 mol % of yttria and about 90 mol % to about 95 mol % of zirconia. In some examples, the thermal barrier coating 106 and/or the yttria-stabilized zirconia contains 7% YSZ, which is (ZrO₂)_{0.93}(Y₂O₃)_{0.07} or 8% YSZ, which is (ZrO₂)_{0.92}(Y₂O₃)_{0.08}.

In other embodiments, the thermal barrier coating 106 can include a rare-earth metal stabilized zirconia or zirconium oxide material. For example, the thermal barrier coating 106 can include compounds with a formula of M₂Zr₂O₇, where M is one or more rare-earth metals selected from La, Ce, Pr, Nd, Pm, Sm, Eu, and/or Gd. In some embodiments, the thermal barrier coating 106 can include a strontium stabilized zirconia or zirconium oxide material, such as SrZrO₃, other ceramics, or combinations thereof.

The thermal barrier coating 106 can be deposited, produced, or otherwise formed on the bond coating 104 by one or more deposition processes. In some embodiments, the thermal barrier coating 106 can be deposited by EBPVD, thermal spray, plasma spray, suspension plasma spray, sol-gel, or combinations thereof. The thermal barrier coating 106 has a thickness of about 50 nm, about 100 nm, about 250 nm, about 500 nm, about 800 nm, about 1 μm, or about 5 μm to about 10 μm, about 20 μm, about 30 μm, about 50 μm, about 80 μm, about 100 μm, about 200 μm, about 300 μm, or about 500 μm. For example, bond coating 104 has a thickness of about 50 nm to about 500 μm, about 50 nm to about 300 μm, about 50 nm to about 100 μm, about 100 nm to about 500 μm, about 100 nm to about 300 μm, about 100 nm to about 100 μm, about 100 nm to about 50 μm, about 100 nm to about 25 μm, about 100 nm to about 10 μm, about 100 nm to about 5 μm, about 100 nm to about 1 μm, about 500 nm to about 50 μm, about 500 nm to about 25 μm, about 500 nm to about 10 μm, about 500 nm to about 5 μm, about 500 nm to about 1 μm, about 1 μm to about 50 μm, or about 1 μm to about 25 μm.

As depicted in FIG. 1, the oxide coating 110 is deposited, formed, or otherwise disposed on the thermal barrier coating 106. The oxide coating 110 can include one layer or multiple layers of the same or different compositions. In some aspects, the oxide coating 110 can contain 1, 2, 3, 4, or more different types of oxide compounds. The oxide coating 110 contains oxides of aluminum, gadolinium, calcium, titanium, magnesium, lanthanum, cerium, zirconium, rhenium, hafnium, dopants thereof, or any combination thereof.

In one or more examples, the oxide coating 110 contains aluminum oxide, gadolinium oxide, calcium oxide, titanium oxide, magnesium oxide, dopants thereof, or any combination thereof. In other examples, the oxide coating 110 contains aluminum gadolinium oxide, lanthanum cerium oxide, lanthanum zirconium oxide, rhenium aluminum oxide, rhenium zirconium oxide, rhenium hafnium oxide, dopants thereof, or any combination thereof. In some examples, the oxide coating 110 is a film containing a mixture of aluminum oxide and gadolinium oxide, a mixture of calcium oxide and gadolinium oxide, a mixture of aluminum oxide and titanium oxide, a mixture of gadolinium oxide and magnesium oxide, dopants thereof, or any combination thereof.

The oxide coating 110 can be deposited, produced, or otherwise formed by one, two, or more vapor deposition processes, such as ALD, PE-ALD, CVD, PE-CVD, PVD, or combinations thereof. The oxide coating 110 can optionally be annealed to enhance inter-diffusion of the elements within the film. The oxide coating 110 can be heated to a temperature of about 500° C., about 800° C., or about 1,000° C. to about 1,100° C., about 1,200° C., about 1,300° C., or about 1,400° C. for about 1 hour, about 2 hours, about 5 hours, or about 10 hours to about 12 hours, about 15 hours, about 18 hours, about 20 hours, or about 24 hours during an annealing process.

The oxide coating 110 has a thickness of about 10 nm, about 20 nm, about 30 nm, about 50 nm, about 100 nm, about 200 nm, about 350 nm, about 500 nm, about 650 nm, about 800 nm, or about 1 μm to about 1.5 μm, about 2 μm, about 3 μm, about 4 μm, about 5 μm, about 6 μm, about 8 μm, or about 10 μm. For example, the oxide coating 110 has a thickness of about 10 nm to about 10 μm, about 10 nm to about 8 μm, about 10 nm to about 6 μm, about 10 nm to about 5 μm, about 10 nm to about 3 μm, about 10 nm to about 1 μm, about 10 nm to about 800 nm, about 10 nm to about 500 nm, about 10 nm to about 300 nm, about 10 nm to about 200 nm, about 10 nm to about 100 nm, about 10 nm to about 50 nm, about 150 nm to about 10 μm, about 150 nm to about 8 μm, about 150 nm to about 6 μm, about 150 nm to about 5 μm, about 150 nm to about 3 μm, about 150 nm to about 1 μm, about 150 nm to about 800 nm, about 150 nm to about 500 nm, about 150 nm to about 300 nm, about 150 nm to about 200 nm, about 500 nm to about 10 μm, about 500 nm to about 8 μm, about 500 nm to about 6 μm, about 500 nm to about 5 μm, about 500 nm to about 3 μm, about 500 nm to about 1 μm, or about 500 nm to about 800 nm.

FIG. 2 is a schematic cross-sectional view of a protected aerospace component 200 containing a protective coating 230 disposed on the substrate 102, according to one or more embodiments described and discussed herein. The protective coating 230 contains the bond coating 104 disposed on the substrate 102, the thermal barrier coating 106 disposed on the bond coating 104, and an oxide coating 210 disposed on the thermal barrier coating 106. The oxide coating 210 contains a first film 212 disposed on the thermal barrier coating 106 and a second film 214 disposed on the first film 212.

Each of the first film 212 and the second film 214 can independently contain one layer or multiple layers of the same or different compositions. In some aspects, each of the first film 212 and the second film 214 can independently contain 1, 2, 3, 4, or more different types of oxide compounds, such as different metal oxides. The oxide coating 210 contains oxides of aluminum, gadolinium, calcium, titanium, magnesium, lanthanum, cerium, zirconium, rhenium, hafnium, dopants thereof, or any combination thereof. In one or more embodiments, the first film 212 contains a first metal oxide and the second film 214 contains a second metal oxide. The first metal oxide has a different composition than the second metal oxide. In some examples, the first metal oxide can have one or more different types of metals than the second metal oxide. In other examples, the first metal oxide can have a different stoichiometric amount or ratio of oxygen than the second metal oxide. Each of the first film 212 and the second film 214 of the oxide coating 210 can independently be deposited, produced, or otherwise formed by one, two, or more vapor deposition processes, such as ALD, PE-ALD, CVD, PE-CVD, PVD, or combinations thereof.

In one or more examples, the first film 212 contains gadolinium oxide and the second film 214 contains aluminum oxide. In other examples, the first film 212 contains a mixture of aluminum oxide and gadolinium oxide and the second film 214 contains aluminum oxide. In some examples, the first film 212 contains gadolinium oxide and the second film 214 contains calcium oxide. In other examples, the first film 212 contains a mixture of calcium oxide and gadolinium oxide and the second film 214 contains calcium oxide. In one or more examples, the first film 212 contains a mixture of calcium oxide and gadolinium oxide and the second film 214 contains aluminum oxide. In other examples, the first film 212 contains gadolinium oxide and the second film 214 contains titanium oxide. In some examples, the first film 212 contains a mixture of titanium oxide and gadolinium oxide and the second film 214 contains titanium oxide. In one or more examples, the first film 212 contains a mixture of titanium oxide and gadolinium oxide and the second film 214 contains aluminum oxide. In other examples, the first film 212 contains a mixture of titanium oxide and gadolinium oxide and the second film 214 contains calcium oxide. In some examples, the first film 212 contains gadolinium oxide and the second film 214 contains magnesium oxide. In other examples, the first film 212 contains a mixture of magnesium oxide and gadolinium oxide and the second film 214 contains magnesium oxide. In some examples, the first film 212 contains a mixture of magnesium oxide and gadolinium oxide and the second film 214 contains aluminum oxide. In other examples, the first film 212 contains a mixture of magnesium oxide and gadolinium oxide and the second film 214 contains calcium oxide.

The oxide coating 210, the first film 212, and/or the second film 214 can independently have a thickness of about 1 nm, about 5 nm, about 10 nm, about 20 nm, about 30 nm, about 50 nm, about 100 nm, about 200 nm, about 350 nm, about 500 nm, about 650 nm, about 800 nm, or about 1 μm to about 1.5 μm, about 2 μm, about 3 μm, about 4 μm, about 5 μm, about 6 μm, about 8 μm, or about 10 μm. For example, the oxide coating 210, the first film 212, and/or the second film 214 can independently have a thickness of about 1 nm to about 10 μm, about 1 nm to about 8 μm, about 1 nm to about 6 μm, about 1 nm to about 5 μm, about 1 nm to about 3 μm, about 1 nm to about 1 μm, about 1 nm to about 800 nm, about 1 nm to about 500 nm, about 1 nm to about 300 nm, about 1 nm to about 200 nm, about 1 nm to about 100 nm, about 1 nm to about 50 nm, about 10 nm to about 10 μm, about 10 nm to about 8 μm, about 10 nm to about 6 μm, about 10 nm to about 5 μm, about 10 nm to about 3 μm, about 10 nm to about 1 μm, about 10 nm to about 800 nm, about 10 nm to about 500 nm, about 10 nm to about 300 nm, about 10 nm to about 200 nm, about 10 nm to about 100 nm, about 10 nm to about 50 nm, about 150 nm to about 10 μm, about 150 nm to about 8 μm, about 150 nm to about 6 μm, about 150 nm to about 5 μm, about 150 nm to about 3 μm, about 150 nm to about 1 μm, about 150 nm to about 800 nm, about 150 nm to about 500 nm, about 150 nm to about 300 nm, about 150 nm to about 200 nm, about 500 nm to about 10 μm, about 500 nm to about 8 μm, about 500 nm to about 6 μm, about 500 nm to about 5 μm, about 500 nm to about 3 μm, about 500 nm to about 1 μm, or about 500 nm to about 800 nm.

The oxide coating 210, as a whole, or each of the first film 212 and the second film 214 can optionally be annealed to enhance inter-diffusion of the elements within the film. The oxide coating 210 can be heated to a temperature of about 500° C., about 800° C., or about 1,000° C. to about 1,100° C., about 1,200° C., about 1,300° C., or about 1,400° C. for about 1 hour, about 2 hours, about 5 hours, or about 10 hours to about 12 hours, about 15 hours, about 18 hours, about 20 hours, or about 24 hours during an annealing process.

FIG. 3 is a schematic cross-sectional view of a protected aerospace component 300 containing a protective coating 330 disposed on the substrate 102, according to one or more embodiments described and discussed herein. The protective coating 330 contains the bond coating 104 disposed on the substrate 102, the thermal barrier coating 106 disposed on the bond coating 104, an oxide coating 310 disposed on the thermal barrier coating 106, and a capping layer 320 disposed on the oxide coating 310.

The oxide coating 310 contains a film stack which contains two, three, or more pairs of a first film 312 and a second film 314. For example, the film stack of the oxide coating 310 can have from 2, 3, 4, 5, 6, 8, 10, or 12 pairs of the first and second films 312, 314 to about 15, about 20, about 30, about 40, about 50, about 65, about 80, about 100, about 150, about 200, or more pairs of the first and second films 312, 314. The oxide coating 310 contains the first film 312 disposed on the thermal barrier coating 106 and the second film 314 disposed on the first film 312. In one or more examples, the initial first film 312 is deposited on the thermal barrier coating 106 and the capping layer 320 is deposited on the final second film 314, depending on how many pairs of the first and second films 312, 314 are deposited to produce the oxide coating 310.

The first film 312 contains a first metal oxide and the second film 314 contains a second metal oxide, and the first metal oxide has a different composition than the second metal oxide. In some examples, the first metal oxide can have one or more different types of metals than the second metal oxide. In other examples, the first metal oxide can have a different stoichiometric amount or ratio of oxygen than the second metal oxide. Each of the first film 312 and the second film 314 can independently contain one layer or multiple layers of the same or different compositions. In some aspects, each of the first film 312 and the second film 314 can independently contain 1, 2, 3, 4, or more different types of oxide compounds, such as different metal oxides. The oxide coating 310 contains oxides of aluminum, gadolinium, calcium, titanium, magnesium, lanthanum, cerium, zirconium, rhenium, hafnium, dopants thereof, or any combination thereof.

The first film 312 contains aluminum oxide, calcium oxide, magnesium oxide, titanium oxide, zinc oxide, dopants thereof, or any combination thereof. The second film 314 contains gadolinium oxide or a dopant thereof. The capping layer 320 contains aluminum oxide, calcium oxide, magnesium oxide, dopants thereof, or any combination thereof. Each of the first film 312, the second film 314, and/or the capping layer 320 can independently be deposited, produced, or otherwise formed by one, two, or more vapor deposition processes, such as ALD, PE-ALD, CVD, PE-CVD, PVD, or combinations thereof.

The oxide coating 310, the first film 312, the second film 314, and/or the capping layer 320 can independently have a thickness of about 1 nm, about 5 nm, about 10 nm, about 20 nm, about 30 nm, about 50 nm, about 100 nm, about 200 nm, about 350 nm, about 500 nm, about 650 nm, about 800 nm, or about 1 μm to about 1.5 μm, about 2 μm, about 3 μm, about 4 μm, about 5 μm, about 6 μm, about 8 μm, or about 10 μm. For example, the oxide coating 310, the first film 312, the second film 314, and/or the capping layer 320 can independently have a thickness of about 1 nm to about 10 μm, about 1 nm to about 8 μm, about 1 nm to about 6 μm, about 1 nm to about 5 μm, about 1 nm to about 3 μm, about 1 nm to about 1 μm, about 1 nm to about 800 nm, about 1 nm to about 500 nm, about 1 nm to about 300 nm, about 1 nm to about 200 nm, about 1 nm to about 100 nm, about 1 nm to about 50 nm, about 10 nm to about 10 μm, about 10 nm to about 8 μm, about 10 nm to about 6 μm, about 10 nm to about 5 μm, about 10 nm to about 3 μm, about 10 nm to about 1 μm, about 10 nm to about 800 nm, about 10 nm to about 500 nm, about 10 nm to about 300 nm, about 10 nm to about 200 nm, about 10 nm to about 100 nm, about 10 nm to about 50 nm, about 150 nm to about 10 μm, about 150 nm to about 8 μm, about 150 nm to about 6 μm, about 150 nm to about 5 μm, about 150 nm to about 3 μm, about 150 nm to about 1 μm, about 150 nm to about 800 nm, about 150 nm to about 500 nm, about 150 nm to about 300 nm, about 150 nm to about 200 nm, about 500 nm to about 10 μm, about 500 nm to about 8 μm, about 500 nm to about 6 μm, about 500 nm to about 5 μm, about 500 nm to about 3 μm, about 500 nm to about 1 μm, or about 500 nm to about 800 nm.

The oxide coating 310, as a whole, or each of the first film 312, the second film 314, and/or the capping layer 320 can optionally be annealed to enhance inter-diffusion of the elements within the film. The oxide coating 310 can be heated to a temperature of about 500° C., about 800° C., or about 1,000° C. to about 1,100° C., about 1,200° C., about 1,300° C., or about 1,400° C. for about 1 hour, about 2 hours, about 5 hours, or about 10 hours to about 12 hours, about 15 hours, about 18 hours, about 20 hours, or about 24 hours during an annealing process.

In one or more embodiments, a method for preparing or otherwise forming the protective coating 130, 230, 330 on the substrate 102 (e.g., an aerospace component) is provided and includes depositing the bond coating 104 on the substrate 102 (e.g., a nickel-based superalloy substrate), depositing the thermal barrier coating 106 containing yttria-stabilized zirconia on the bond coating 104, and forming the oxide coating 110, 210, 310 on the thermal barrier coating 106 by depositing metal oxides by ALD or another vapor deposition process. The bond coating 104 includes an alloy containing chromium, aluminum, a first element selected from nickel or cobalt, and a second element selected from hafnium, tungsten, zirconium, yttrium, or lanthanide. In some embodiments, the first film 212, 312 contains a first metal oxide and the second film 214, 314 contains a second metal oxide, and the first metal oxide has a different composition than the second metal oxide. In other embodiments, the method further includes depositing the capping layer 320 on the oxide coating 310. The capping layer 320 contains aluminum oxide, calcium oxide, magnesium oxide, dopants thereof, or any combination thereof.

### Vapor Deposition Processes

In one or more embodiments, the aerospace component can be exposed to a first precursor and an oxidizing agent to form the first film on the substrate or aerospace component by a vapor deposition process. The vapor deposition process can be an ALD process, a PE-ALD process, a thermal CVD process, a PE-CVD process, or any combination thereof.

One or more aluminum precursors and one or more oxidizing agents can be combined in a vapor deposition process to produce aluminum oxide. Exemplary oxidizing agents can be or include water (e.g., steam), oxygen (O₂), atomic oxygen, ozone, nitrous oxide, one or more inorganic peroxides (e.g., hydrogen peroxide, calcium peroxide), one or more organic peroxides, one or more alcohols, plasmas thereof, or any combination thereof. The aluminum precursor can be or include one or more aluminum alkyl compounds, one or more aluminum alkoxy compounds, one or more aluminum acetylacetonate compounds, substitutes thereof, complexes thereof, abducts thereof, salts thereof, or any combination thereof. Exemplary aluminum precursors can be or include trimethylaluminum, triethylaluminum, tripropylaluminum, tributylaluminum, trimethoxyaluminum, triethoxyaluminum, tripropoxyaluminum, tributoxyaluminum, aluminum acetylacetonate (Al(acac)₃, also known as, tris(2,4-pentanediono) aluminum), aluminum hexafluoroacetylacetonate (Al(hfac)₃), trisdipivaloylmethanatoaluminum (DPM₃Al; (C₁₁H₁₉O₂)₃Al), isomers thereof, complexes thereof, abducts thereof, salts thereof, or any combination thereof.

One or more hafnium precursors and one or more oxidizing agents can be combined in a vapor deposition process to produce hafnium oxide. The hafnium precursor can be or include one or more hafnium cyclopentadiene compounds, one or more hafnium amino compounds, one or more hafnium alkyl compounds, one or more hafnium alkoxy compounds, substitutes thereof, complexes thereof, abducts thereof, salts thereof, or any combination thereof. Exemplary hafnium precursors can be or include bis(methylcyclopentadiene) dimethylhafnium ((MeCp)₂HfMe₂), bis(methylcyclopentadiene) methylmethoxyhafnium ((MeCp)₂Hf(OMe)(Me)), bis(cyclopentadiene) dimethylhafnium ((Cp)₂HfMe₂), tetra(tert-butoxy) hafnium, hafniumum isopropoxide ((iPrO)₄Hf), tetrakis(dimethylamino) hafnium (TDMAH), tetrakis(diethylamino) hafnium (TDEAH), tetrakis(ethylmethylamino) hafnium (TEMAH), isomers thereof, complexes thereof, abducts thereof, salts thereof, or any combination thereof.

One or more titanium precursors and one or more oxidizing agents can be combined in a vapor deposition process to produce titanium oxide. The titanium precursor can be or include one or more titanium cyclopentadiene compounds, one or more titanium amino compounds, one or more titanium alkyl compounds, one or more titanium alkoxy compounds, substitutes thereof, complexes thereof, abducts thereof, salts thereof, or any combination thereof. Exemplary titanium precursors can be or include bis(methylcyclopentadiene) dimethyltitanium ((MeCp)₂TiMe₂), bis(methylcyclopentadiene) methylmethoxytitanium ((MeCp)₂Ti(OMe)(Me)), bis(cyclopentadiene) dimethyltitanium ((Cp)₂TiMe₂), tetra(tert-butoxy) titanium, titaniumum isopropoxide ((iPrO)₄Ti), tetrakis(dimethylamino) titanium (TDMAT), tetrakis(diethylamino) titanium (TDEAT), tetrakis(ethylmethylamino) titanium (TEMAT), isomers thereof, complexes thereof, abducts thereof, salts thereof, or any combination thereof.

One or more zirconium precursors and one or more oxidizing agents can be combined in a vapor deposition process to produce zirconium oxide. The zirconium precursor can be or include one or more zirconium cyclopentadiene compounds, one or more zirconium amino compounds, one or more zirconium alkyl compounds, one or more zirconium alkoxy compounds, substitutes thereof, complexes thereof, abducts thereof, salts thereof, or any combination thereof. Exemplary zirconium precursors can be or include bis(methylcyclopentadiene) dimethylzirconium ((MeCp)₂ZrMe₂), bis(methylcyclopentadiene) methylmethoxyzirconium ((MeCp)₂Zr(OMe)(Me)), bis(cyclopentadiene) dimethylzirconium ((Cp)₂ZrMe₂), tetra(tert-butoxy) zirconium, zirconiumum isopropoxide ((iPrO)₄Zr), tetrakis(dimethylamino) zirconium, tetrakis(diethylamino) zirconium, tetrakis(ethylmethylamino) zirconium, isomers thereof, complexes thereof, abducts thereof, salts thereof, or any combination thereof.

One or more lanthanum precursors and one or more oxidizing agents can be combined in a vapor deposition process to produce lanthanum oxide. The lanthanum precursor can be or include one or more lanthanum cyclopentadiene compounds, one or more lanthanum amino compounds, one or more lanthanum alkyl compounds, one or more lanthanum alkoxy compounds, substitutes thereof, complexes thereof, abducts thereof, salts thereof, or any combination thereof. Exemplary lanthanum precursors can be or include lanthanum(III) iso-propoxide (C₉H₂₁LaO₃), tris[N,N-bis(trimethylsilyl)amide] lanthanum(III) (La(N(Si(CH₃)₃)₂)₃), tris(cyclopentadienyl) lanthanum(III) (La(C₅H₅)₃), tris(tetramethylcyclopentadienyl) lanthanum(III) (La((CH₃)₄C₅H)₃), isomers thereof, complexes thereof, abducts thereof, salts thereof, or any combination thereof.

One or more zinc precursors and one or more oxidizing agents can be combined in a vapor deposition process to produce zinc oxide. The zinc precursor can be or include one or more zinc alkyl compounds, one or more zinc alkoxy compounds, one or more zinc dionate compounds, substitutes thereof, complexes thereof, abducts thereof, salts thereof, or any combination thereof. Exemplary zinc precursors can be or include diethylzinc (DEZ), bis(2,2,6,6-tetramethyl-3,5-heptanedionato)zinc (Zn(TMHD)₂), bis[4,4,4-trifluoro-1-(2-thienyl-1,3-butanedionato]zinc (TMEDA), zinc methoxide (Zn(OCH₃)₂), isomers thereof, complexes thereof, abducts thereof, salts thereof, or any combination thereof.

One or more calcium precursors and one or more oxidizing agents can be combined in a vapor deposition process to produce calcium oxide. The calcium precursor can be or include of one or more calcium cyclopentadiene compounds, one or more of calcium alkyl compounds, one or more of calcium alkoxy compounds, one or more of calcium dionate compounds, substitutes thereof, complexes thereof, abducts thereof, salts thereof, or any combination thereof. Exemplary calcium precursors can be or include bis(N,N′-diisopropylformamidinato) calcium(II) dimer (C₂₈H₆₀Ca₂N₈), bis(6,6,7,7,8,8,8-heptafluoro-2,2-dimethyl-3,5-octanedionate) calcium (Ca(C₃F₇OOCHCOC(CH₃)₃)₂), bis(2,2,6,6-tetramethyl-3,5-heptanedionato) calcium (Ca(TMHD)₂), bis(pentamethylcyclopentadienyl) calcium tetrahydrofuran ((CH₃)₅C₅]₂Ca(C₄H₈O)₂), isomers thereof, complexes thereof, abducts thereof, salts thereof, or any combination thereof.

One or more magnesium precursors and one or more oxidizing agents can be combined in a vapor deposition process to produce magnesium oxide. The magnesium precursor can be or include one or more magnesium cyclopentadiene compounds, one or more of magnesium alkyl compounds, one or more of magnesium alkoxy compounds, one or more of magnesium dionate compounds, substitutes thereof, complexes thereof, abducts thereof, salts thereof, or any combination thereof. Exemplary magnesium precursors can be or include bis(cyclopentadienyl) magnesium (C₁₀H₁₀Mg), bis(ethylcyclopentadienyl) magnesium ((C₂H₅C₅H₄)₂Mg), bis(pentamethylcyclopentadienyl) magnesium ((CH₃)₅C₅)₂Mg), bis(2,2,6,6-tetramethyl-3,5-heptanedionato) magnesium (Mg(TMHD)₂), isomers thereof, complexes thereof, abducts thereof, salts thereof, or any combination thereof.

One or more gadolinium precursors and one or more oxidizing agents can be combined in a vapor deposition process to produce gadolinium oxide. The gadolinium precursor can be or include one or more gadolinium cyclopentadiene compounds, one or more of gadolinium carbonyl compounds, one or more of gadolinium dionate compounds, one or more of gadolinium amino compounds, substitutes thereof, complexes thereof, abducts thereof, salts thereof, or any combination thereof. Exemplary gadolinium precursors can be or include tris(cyclopentadienyl) gadolinium (Gd(C₅H₅)₃), tris(tetramethylcyclopentadienyl) gadolinium (Gd((CH₃)₄C₅H)₃), tris(2,2,6,6-tetramethyl-3,5-heptanedionato) gadolinium (Gd(TMHD)₃), gadolinium(III) tris[N,N-bis(trimethylsilyl)amide](Gd(N(Si(CH₃)₃)₂)₃), isomers thereof, complexes thereof, abducts thereof, salts thereof, or any combination thereof.

One or more rhenium precursors and one or more oxidizing agents can be combined in a vapor deposition process to produce rhenium oxide. The rhenium precursor can be or include one or more rhenium cyclopentadiene compounds, one or more of rhenium carbonyl compounds, one or more of rhenium dionate compounds, substitutes thereof, complexes thereof, abducts thereof, salts thereof, or any combination thereof. Exemplary rhenium precursors can be or include methyltrioxorhenium (ReO₃Me), dirhenium decacarbonyl (Re₂(CO)₁₀), isomers thereof, complexes thereof, abducts thereof, salts thereof, or any combination thereof.

One or more cerium precursors and one or more oxidizing agents can be combined in a vapor deposition process to produce cerium oxide. The cerium precursor can be or include one or more cerium cyclopentadiene compounds, one or more of cerium dionate compounds, substitutes thereof, complexes thereof, abducts thereof, salts thereof, or any combination thereof. Exemplary cerium precursor can be or include one or more cerium(IV) tetra(2,2,6,6-tetramethyl-3,5-heptanedionate) (Ce(TMHD)₄), tris(cyclopentadiene) cerium ((C₅H₅)₃Ce), tris(propylcyclopentadiene) cerium ([(C₃H₇)C₅H_{4]3}Ce), tris(tetramethylcyclopentadiene) cerium ([(CH₃)₄C₅H]₃Ce), or any combination thereof.

In one or more embodiments, the vapor deposition process is an ALD process and the method includes sequentially exposing the surface of the substrate or aerospace component to the first precursor and the oxidizing agent to form the first film. Each cycle of the ALD process includes exposing the surface of the aerospace component to the first precursor, conducting a pump-purge, exposing the aerospace component to the oxidizing agent, and conducting a pump-purge to form the first film. The order of the first precursor and the oxidizing agent can be reversed, such that the ALD cycle includes exposing the surface of the aerospace component to the oxidizing agent, conducting a pump-purge, exposing the aerospace component to the first precursor, and conducting a pump-purge to form the first film.

In some examples, during each ALD cycle, the substrate or aerospace component is exposed to the first precursor for about 0.1 seconds to about 10 seconds, the oxidizing agent for about 0.1 seconds to about 10 seconds, and the pump-purge for about 0.5 seconds to about 30 seconds. In other examples, during each ALD cycle, the substrate or aerospace component is exposed to the first precursor for about 0.5 seconds to about 3 seconds, the oxidizing agent for about 0.5 seconds to about 3 seconds, and the pump-purge for about 1 second to about 10 seconds.

Each ALD cycle is repeated from 2, 3, 4, 5, 6, 8, about 10, about 12, or about 15 times to about 18, about 20, about 25, about 30, about 40, about 50, about 65, about 80, about 100, about 120, about 150, about 200, about 250, about 300, about 350, about 400, about 500, about 800, about 1,000, or more times to form the first deposited layer. For example, each ALD cycle is repeated from 2 times to about 1,000 times, 2 times to about 800 times, 2 times to about 500 times, 2 times to about 300 times, 2 times to about 250 times, 2 times to about 200 times, 2 times to about 150 times, 2 times to about 120 times, 2 times to about 100 times, 2 times to about 80 times, 2 times to about 50 times, 2 times to about 30 times, 2 times to about 20 times, 2 times to about 15 times, 2 times to about 10 times, 2 times to 5 times, about 8 times to about 1,000 times, about 8 times to about 800 times, about 8 times to about 500 times, about 8 times to about 300 times, about 8 times to about 250 times, about 8 times to about 200 times, about 8 times to about 150 times, about 8 times to about 120 times, about 8 times to about 100 times, about 8 times to about 80 times, about 8 times to about 50 times, about 8 times to about 30 times, about 8 times to about 20 times, about 8 times to about 15 times, about 8 times to about 10 times, about 20 times to about 1,000 times, about 20 times to about 800 times, about 20 times to about 500 times, about 20 times to about 300 times, about 20 times to about 250 times, about 20 times to about 200 times, about 20 times to about 150 times, about 20 times to about 120 times, about 20 times to about 100 times, about 20 times to about 80 times, about 20 times to about 50 times, about 20 times to about 30 times, about 50 times to about 1,000 times, about 50 times to about 500 times, about 50 times to about 350 times, about 50 times to about 300 times, about 50 times to about 250 times, about 50 times to about 150 times, or about 50 times to about 100 times to form the first film.

In other embodiments, the vapor deposition process is a CVD process and the method includes simultaneously exposing the substrate or aerospace component to the first precursor and the oxidizing agent to form the first film. During an ALD process or a CVD process, each of the first precursor and the oxidizing agent can independently include one or more carrier gases. One or more purge gases can be flowed across the aerospace component and/or throughout the processing chamber in between the exposures of the first precursor and the oxidizing agent. In some examples, the same gas may be used as a carrier gas and a purge gas. Exemplary carrier gases and purge gases can independently be or include one or more of nitrogen (N₂), argon, helium, neon, hydrogen (H₂), or any combination thereof.

The first film can have a thickness of about 0.1 nm, about 0.2 nm, about 0.3 nm, about 0.4 nm, about 0.5 nm, about 0.8 nm, about 1 nm, about 2 nm, about 3 nm, about 5 nm, about 8 nm, about 10 nm, about 12 nm, or about 15 nm to about 18 nm, about 20 nm, about 25 nm, about 30 nm, about 40 nm, about 50 nm, about 60 nm, about 80 nm, about 100 nm, about 120 nm, or about 150 nm. For example, the first film can have a thickness of about 0.1 nm to about 150 nm, about 0.2 nm to about 150 nm, about 0.2 nm to about 120 nm, about 0.2 nm to about 100 nm, about 0.2 nm to about 80 nm, about 0.2 nm to about 50 nm, about 0.2 nm to about 40 nm, about 0.2 nm to about 30 nm, about 0.2 nm to about 20 nm, about 0.2 nm to about 10 nm, about 0.2 nm to about 5 nm, about 0.2 nm to about 1 nm, about 0.2 nm to about 0.5 nm, about 0.5 nm to about 150 nm, about 0.5 nm to about 120 nm, about 0.5 nm to about 100 nm, about 0.5 nm to about 80 nm, about 0.5 nm to about 50 nm, about 0.5 nm to about 40 nm, about 0.5 nm to about 30 nm, about 0.5 nm to about 20 nm, about 0.5 nm to about 10 nm, about 0.5 nm to about 5 nm, about 0.5 nm to about 1 nm, about 2 nm to about 150 nm, about 2 nm to about 120 nm, about 2 nm to about 100 nm, about 2 nm to about 80 nm, about 2 nm to about 50 nm, about 2 nm to about 40 nm, about 2 nm to about 30 nm, about 2 nm to about 20 nm, about 2 nm to about 10 nm, about 2 nm to about 5 nm, about 2 nm to about 3 nm, about 10 nm to about 150 nm, about 10 nm to about 120 nm, about 10 nm to about 100 nm, about 10 nm to about 80 nm, about 10 nm to about 50 nm, about 10 nm to about 40 nm, about 10 nm to about 30 nm, about 10 nm to about 20 nm, or about 10 nm to about 15 nm.

In one or more embodiments, the substrate or aerospace component is exposed to a second precursor and the oxidizing agent to form the second film on the first film by an ALD process producing nanolaminate film. The first film and second film have different compositions from each other. In some examples, the first precursor is a different precursor than the second precursor, such as that the first precursor is a source of a first type of metal and the second precursor is a source of a second type of metal and the first and second types of metal are different.

During the ALD process, each of the second precursor and/or the oxidizing agent can independently include one or more carrier gases. One or more purge gases can be flowed across the aerospace component and/or throughout the processing chamber in between the exposures of the second precursor and the oxidizing agent. In some examples, the same gas may be used as a carrier gas and a purge gas. Exemplary carrier gases and purge gases can independently be or include one or more of nitrogen (N₂), argon, helium, neon, hydrogen (H₂), or any combination thereof.

Each cycle of the ALD process includes exposing the aerospace component to the second precursor, conducting a pump-purge, exposing the aerospace component to the oxidizing agent, and conducting a pump-purge to form the second film. The order of the second precursor and the oxidizing agent can be reversed, such that the ALD cycle includes exposing the surface of the aerospace component to the oxidizing agent, conducting a pump-purge, exposing the aerospace component to the second precursor, and conducting a pump-purge to form the second film.

In one or more examples, during each ALD cycle, the substrate or aerospace component is exposed to the second precursor for about 0.1 seconds to about 10 seconds, the oxidizing agent for about 0.1 seconds to about 10 seconds, and the pump-purge for about 0.5 seconds to about 30 seconds. In other examples, during each ALD cycle, the substrate or aerospace component is exposed to the second precursor for about 0.5 seconds to about 3 seconds, the oxidizing agent for about 0.5 seconds to about 3 seconds, and the pump-purge for about 1 second to about 10 seconds.

Each ALD cycle is repeated from 2, 3, 4, 5, 6, 8, about 10, about 12, or about 15 times to about 18, about 20, about 25, about 30, about 40, about 50, about 65, about 80, about 100, about 120, about 150, about 200, about 250, about 300, about 350, about 400, about 500, about 800, about 1,000, or more times to form the second film. For example, each ALD cycle is repeated from 2 times to about 1,000 times, 2 times to about 800 times, 2 times to about 500 times, 2 times to about 300 times, 2 times to about 250 times, 2 times to about 200 times, 2 times to about 150 times, 2 times to about 120 times, 2 times to about 100 times, 2 times to about 80 times, 2 times to about 50 times, 2 times to about 30 times, 2 times to about 20 times, 2 times to about 15 times, 2 times to about 10 times, 2 times to 5 times, about 8 times to about 1,000 times, about 8 times to about 800 times, about 8 times to about 500 times, about 8 times to about 300 times, about 8 times to about 250 times, about 8 times to about 200 times, about 8 times to about 150 times, about 8 times to about 120 times, about 8 times to about 100 times, about 8 times to about 80 times, about 8 times to about 50 times, about 8 times to about 30 times, about 8 times to about 20 times, about 8 times to about 15 times, about 8 times to about 10 times, about 20 times to about 1,000 times, about 20 times to about 800 times, about 20 times to about 500 times, about 20 times to about 300 times, about 20 times to about 250 times, about 20 times to about 200 times, about 20 times to about 150 times, about 20 times to about 120 times, about 20 times to about 100 times, about 20 times to about 80 times, about 20 times to about 50 times, about 20 times to about 30 times, about 50 times to about 1,000 times, about 50 times to about 500 times, about 50 times to about 350 times, about 50 times to about 300 times, about 50 times to about 250 times, about 50 times to about 150 times, or about 50 times to about 100 times to form the second film.

The second film can have a thickness of about 0.1 nm, about 0.2 nm, about 0.3 nm, about 0.4 nm, about 0.5 nm, about 0.8 nm, about 1 nm, about 2 nm, about 3 nm, about 5 nm, about 8 nm, about 10 nm, about 12 nm, or about 15 nm to about 18 nm, about 20 nm, about 25 nm, about 30 nm, about 40 nm, about 50 nm, about 60 nm, about 80 nm, about 100 nm, about 120 nm, or about 150 nm. For example, the second film can have a thickness of about 0.1 nm to about 150 nm, about 0.2 nm to about 150 nm, about 0.2 nm to about 120 nm, about 0.2 nm to about 100 nm, about 0.2 nm to about 80 nm, about 0.2 nm to about 50 nm, about 0.2 nm to about 40 nm, about 0.2 nm to about 30 nm, about 0.2 nm to about 20 nm, about 0.2 nm to about 10 nm, about 0.2 nm to about 5 nm, about 0.2 nm to about 1 nm, about 0.2 nm to about 0.5 nm, about 0.5 nm to about 150 nm, about 0.5 nm to about 120 nm, about 0.5 nm to about 100 nm, about 0.5 nm to about 80 nm, about 0.5 nm to about 50 nm, about 0.5 nm to about 40 nm, about 0.5 nm to about 30 nm, about 0.5 nm to about 20 nm, about 0.5 nm to about 10 nm, about 0.5 nm to about 5 nm, about 0.5 nm to about 1 nm, about 2 nm to about 150 nm, about 2 nm to about 120 nm, about 2 nm to about 100 nm, about 2 nm to about 80 nm, about 2 nm to about 50 nm, about 2 nm to about 40 nm, about 2 nm to about 30 nm, about 2 nm to about 20 nm, about 2 nm to about 10 nm, about 2 nm to about 5 nm, about 2 nm to about 3 nm, about 10 nm to about 150 nm, about 10 nm to about 120 nm, about 10 nm to about 100 nm, about 10 nm to about 80 nm, about 10 nm to about 50 nm, about 10 nm to about 40 nm, about 10 nm to about 30 nm, about 10 nm to about 20 nm, or about 10 nm to about 15 nm.

The method includes deciding whether or not a desired thickness of the metal oxide or the oxide coating 110, 210, 310 has been achieved. If the desired thickness of the metal oxide or the oxide coating 110, 210, 310 has been achieved, then cease depositing material. If the desired thickness of the metal oxide or the oxide coating 110, 210, 310 has not been achieved, then start another deposition cycle of depositing the first film by the vapor deposition process and depositing the second film by the ALD process. The deposition cycle is repeated until achieving the desired thickness of the metal oxide or the oxide coating 110, 210, 310.

In one or more embodiments, the protective coating 330 or the metal oxide or the oxide coating 110, 210, 310 can contain from 2, 3, 4, 5, 6, 7, 8, or 9 pairs of the first and second films to about 10, about 12, about 15, about 20, about 25, about 30, about 40, about 50, about 65, about 80, about 100, about 120, about 150, about 200, about 250, about 300, about 500, about 800, or about 1,000 pairs of the first and second films. For example, the metal oxide or the oxide coating 310 can contain from 1 to about 1,000, 1 to about 800, 1 to about 500, 1 to about 300, 1 to about 250, 1 to about 200, 1 to about 150, 1 to about 120, 1 to about 100, 1 to about 80, 1 to about 65, 1 to about 50, 1 to about 30, 1 to about 20, 1 to about 15, 1 to about 10, 1 to about 8, 1 to about 6, 1 to 5, 1 to 4, 1 to 3, about 5 to about 150, about 5 to about 120, about 5 to about 100, about 5 to about 80, about 5 to about 65, about 5 to about 50, about 5 to about 30, about 5 to about 20, about 5 to about 15, about 5 to about 10, about 5 to about 8, about 5 to about 7, about 10 to about 150, about 10 to about 120, about 10 to about 100, about 10 to about 80, about 10 to about 65, about 10 to about 50, about 10 to about 30, about 10 to about 20, about 10 to about 15, or about 10 to about 12 pairs of the first and second films.

The protective coating 130, 230, 330 or the metal oxide or the oxide coating 110, 210, 310 can have a thickness of about 1 nm, about 2 nm, about 3 nm, about 5 nm, about 8 nm, about 10 nm, about 12 nm, about 15 nm, about 20 nm, about 30 nm, about 50 nm, about 60 nm, about 80 nm, about 100 nm, or about 120 nm to about 150 nm, about 180 nm, about 200 nm, about 250 nm, about 300 nm, about 350 nm, about 400 nm, about 500 nm, about 800 nm, about 1,000 nm, about 2,000 nm, about 3,000 nm, about 4,000 nm, about 5,000 nm, about 6,000 nm, about 7,000 nm, about 8,000 nm, about 9,000 nm, about 10,000 nm, or thicker. In some examples, the protective coating 130, 230, 330 or the metal oxide or the oxide coating 110, 210, 310 can have a thickness of less than 10 μm (less than 10,000 nm). For example, the protective coating 130, 230, 330 or the metal oxide or the oxide coating 110, 210, 310 can have a thickness of about 1 nm to less than 10,000 nm, about 1 nm to about 8,000 nm, about 1 nm to about 6,000 nm, about 1 nm to about 5,000 nm, about 1 nm to about 3,000 nm, about 1 nm to about 2,000 nm, about 1 nm to about 1,500 nm, about 1 nm to about 1,000 nm, about 1 nm to about 500 nm, about 1 nm to about 400 nm, about 1 nm to about 300 nm, about 1 nm to about 250 nm, about 1 nm to about 200 nm, about 1 nm to about 150 nm, about 1 nm to about 100 nm, about 1 nm to about 80 nm, about 1 nm to about 50 nm, about 20 nm to about 500 nm, about 20 nm to about 400 nm, about 20 nm to about 300 nm, about 20 nm to about 250 nm, about 20 nm to about 200 nm, about 20 nm to about 150 nm, about 20 nm to about 100 nm, about 20 nm to about 80 nm, about 20 nm to about 50 nm, about 30 nm to about 400 nm, about 30 nm to about 200 nm, about 50 nm to about 500 nm, about 50 nm to about 400 nm, about 50 nm to about 300 nm, about 50 nm to about 250 nm, about 50 nm to about 200 nm, about 50 nm to about 150 nm, about 50 nm to about 100 nm, about 80 nm to about 250 nm, about 80 nm to about 200 nm, about 80 nm to about 150 nm, about 80 nm to about 100 nm, about 50 nm to about 80 nm, about 100 nm to about 500 nm, about 100 nm to about 400 nm, about 100 nm to about 300 nm, about 100 nm to about 250 nm, about 100 nm to about 200 nm, or about 100 nm to about 150 nm.

The metal oxide or the oxide coating 110, 210, 310 can optionally be exposed to one or more annealing processes. In some examples, the metal oxide or the oxide coating 110, 210, 310 can be converted into the coalesced film 240 during the annealing process. During the annealing process, the high temperature coalesces the layers within the metal oxide or the oxide coating 110, 210, 310 into a single structure where the new crystalline assembly enhances the integrity and protective properties of the coalesced film 240. In other examples, the metal oxide or the oxide coating 110, 210, 310 can be heated and densified during the annealing process, but still maintained as a nanolaminate film stack. The annealing process can be or include a thermal anneal, a plasma anneal, an ultraviolet anneal, a laser anneal, or any combination thereof.

The metal oxide or the oxide coating 110, 210, 310 disposed on the substrate or aerospace component is heated to a temperature of about 400° C., about 500° C., about 600° C., or about 700° C. to about 750° C., about 800° C., about 900° C., about 1,000° C., about 1,100° C., about 1,200° C., or greater during the annealing process. For example, the metal oxide or the oxide coating 110, 210, 310 disposed on the substrate or aerospace component is heated to a temperature of about 400° C. to about 1,200° C., about 400° C. to about 1,100° C., about 400° C. to about 1,000° C., about 400° C. to about 900° C., about 400° C. to about 800° C., about 400° C. to about 700° C., about 400° C. to about 600° C., about 400° C. to about 500° C., about 550° C. to about 1,200° C., about 550° C. to about 1,100° C., about 550° C. to about 1,000° C., about 550° C. to about 900° C., about 550° C. to about 800° C., about 550° C. to about 700° C., about 550° C. to about 600° C., about 700° C. to about 1,200° C., about 700° C. to about 1,100° C., about 700° C. to about 1,000° C., about 700° C. to about 900° C., about 700° C. to about 800° C., about 850° C. to about 1,200° C., about 850° C. to about 1,100° C., about 850° C. to about 1,000° C., or about 850° C. to about 900° C. during the annealing process.

The metal oxide or the oxide coating 110, 210, 310 can be under a vacuum at a low pressure (e.g., from about 0.1 Torr to less than 760 Torr), at ambient pressure (e.g., about 760 Torr), and/or at a high pressure (e.g., from greater than 760 Torr (1 atm) to about 3,678 Torr (about 5 atm)) during the annealing process. The metal oxide or the oxide coating 110, 210, 310 can be exposed to an atmosphere containing one or more gases during the annealing process. Exemplary gases used during the annealing process can be or include nitrogen (N₂), argon, helium, hydrogen (H₂), oxygen (O₂), or any combinations thereof. The annealing process can be performed for about 0.01 seconds to about 10 minutes. In some examples, the annealing process can be a thermal anneal and lasts for about 1 minute, about 5 minutes, about 10 minutes, or about 30 minutes to about 1 hour, about 2 hours, about 5 hours, or about 24 hours. In other examples, the annealing process can be a laser anneal or a spike anneal and lasts for about 1 millisecond, about 100 millisecond, or about 1 second to about 5 seconds, about 10 seconds, or about 15 seconds.

In one or more embodiments, the oxide coating 110, 210, 310 can be converted to a coalesced film can have a thickness of about 1 nm, about 2 nm, about 3 nm, about 5 nm, about 8 nm, about 10 nm, about 12 nm, about 15 nm, about 20 nm, about 30 nm, about 50 nm, about 60 nm, about 80 nm, about 100 nm, or about 120 nm to about 150 nm, about 180 nm, about 200 nm, about 250 nm, about 300 nm, about 350 nm, about 400 nm, about 500 nm, about 700 nm, about 850 nm, about 1,000 nm, about 1,200 nm, about 1,500 nm, about 2,000 nm, about 3,000 nm, about 4,000 nm, about 5,000 nm, about 6,000 nm, about 7,000 nm, about 8,000 nm, about 9,000 nm, about 10,000 nm, or thicker. In some examples, the protective coating 250 or the coalesced film 240 can have a thickness of less than 10 μm (less than 10,000 nm). For example, the oxide coating 110, 210, 310 can have a thickness of about 1 nm to less than 10,000 nm, about 1 nm to about 8,000 nm, about 1 nm to about 6,000 nm, about 1 nm to about 5,000 nm, about 1 nm to about 3,000 nm, about 1 nm to about 2,000 nm, about 1 nm to about 1,500 nm, about 1 nm to about 1,000 nm, about 1 nm to about 500 nm, about 1 nm to about 400 nm, about 1 nm to about 300 nm, about 1 nm to about 250 nm, about 1 nm to about 200 nm, about 1 nm to about 150 nm, about 1 nm to about 100 nm, about 1 nm to about 80 nm, about 1 nm to about 50 nm, about 20 nm to about 500 nm, about 20 nm to about 400 nm, about 20 nm to about 300 nm, about 20 nm to about 250 nm, about 20 nm to about 200 nm, about 20 nm to about 150 nm, about 20 nm to about 100 nm, about 20 nm to about 80 nm, about 20 nm to about 50 nm, about 30 nm to about 400 nm, about 30 nm to about 200 nm, about 50 nm to about 500 nm, about 50 nm to about 400 nm, about 50 nm to about 300 nm, about 50 nm to about 250 nm, about 50 nm to about 200 nm, about 50 nm to about 150 nm, about 50 nm to about 100 nm, about 80 nm to about 250 nm, about 80 nm to about 200 nm, about 80 nm to about 150 nm, about 80 nm to about 100 nm, about 50 nm to about 80 nm, about 100 nm to about 500 nm, about 100 nm to about 400 nm, about 100 nm to about 300 nm, about 100 nm to about 250 nm, about 100 nm to about 200 nm, or about 100 nm to about 150 nm.

In one or more embodiments, the oxide coating 110, 210, 310 can have a relatively high degree of uniformity. The oxide coating 110, 210, 310 can have a uniformity of less than 50%, less than 40%, or less than 30% of the thickness of the respective coating. The oxide coating 110, 210, 310 can independently have a uniformity from about 0%, about 0.5%, about 1%, about 2%, about 3%, about 5%, about 8%, or about 10% to about 12%, about 15%, about 18%, about 20%, about 22%, about 25%, about 28%, about 30%, about 35%, about 40%, about 45%, or less than 50% of the thickness. For example, the oxide coating 110, 210, 310 can independently have a uniformity from about 0% to about 50%, about 0% to about 40%, about 0% to about 30%, about 0% to less than 30%, about 0% to about 28%, about 0% to about 25%, about 0% to about 20%, about 0% to about 15%, about 0% to about 10%, about 0% to about 8%, about 0% to about 5%, about 0% to about 3%, about 0% to about 2%, about 0% to about 1%, about 1% to about 50%, about 1% to about 40%, about 1% to about 30%, about 1% to less than 30%, about 1% to about 28%, about 1% to about 25%, about 1% to about 20%, about 1% to about 15%, about 1% to about 10%, about 1% to about 8%, about 1% to about 5%, about 1% to about 3%, about 1% to about 2%, about 5% to about 50%, about 5% to about 40%, about 5% to about 30%, about 5% to less than 30%, about 5% to about 28%, about 5% to about 25%, about 5% to about 20%, about 5% to about 15%, about 5% to about 10%, about 5% to about 8%, about 10% to about 50%, about 10% to about 40%, about 10% to about 30%, about 10% to less than 30%, about 10% to about 28%, about 10% to about 25%, about 10% to about 20%, about 10% to about 15%, or about 10% to about 12% of the thickness.

In some embodiments, the oxide coating 110, 210, 310 can contain, be formed, or otherwise produced with different ratios of metals throughout the material, such as a doping metal or grading metal contained within a base metal, where any of the metal can be in any chemically oxidized form (e.g., oxide, nitride, silicide, carbide, or combinations thereof). In one or more examples, the first film is deposited to first thickness and the second film is deposited to a second thickness, where the first thickness or less than or greater than the second thickness. For example, the first film can be deposited by two or more (3, 4, 5, 6, 7, 8, 9, 10, or more) ALD cycles to produce the respectively same amount of sub-layers (e.g., one sub-layer for each ALD cycle), and then the second film can be deposited by one ALD cycle or a number of ALD cycles that is less than or greater than the number of ALD cycles used to deposit the first film. In other examples, the first film can be deposited by CVD to a first thickness and the second film is deposited by ALD to a second thickness which is less than the first thickness.

In other embodiments, an ALD process can be used to deposit the first film and/or the second film where the deposited material is doped by including a dopant precursor during the ALD process. The dopant precursor can be or include one or more of the precursors described and discussed herein, as well as other chemical precursors. In some examples, the dopant precursor can be included in a separate ALD cycle relative to the ALD cycles used to deposit the base material. In other examples, the dopant precursor can be co-injected with any of the chemical precursors used during the ALD cycle. In further examples, the dopant precursor can be injected separate from the chemical precursors during the ALD cycle. For example, one ALD cycle can include exposing the aerospace component to: the first precursor, a pump-purge, the dopant precursor, a pump-purge, the oxidizing agent, and a pump-purge to form the deposited layer. In some examples, one ALD cycle can include exposing the aerospace component to: the dopant precursor, a pump-purge, the first precursor, a pump-purge, the oxidizing agent, and a pump-purge to form the deposited layer. In other examples, one ALD cycle can include exposing the aerospace component to: the first precursor, the dopant precursor, a pump-purge, the oxidizing agent, and a pump-purge to form the deposited layer.

The protective coating, as described and discussed herein, can be or include one or more of laminate film stacks, coalesced films, graded compositions, and/or monolithic films which are deposited or otherwise formed on any surface of an aerospace component. The protective coatings are conformal and substantially coat rough surface features following surface topology, including in open pores, blind holes, and non-line-of-sight regions of a surface. The protective coatings do not substantially increase surface roughness, and in some embodiments, the protective coatings may reduce surface roughness by conformally coating roughness until it coalesces. The protective coatings may contain particles from the deposition that are substantially larger than the roughness of the aerospace component, but are considered separate from the monolithic film. The protective coatings are substantially well adhered and pinhole free. The thickness of the protective coatings varies within 1-sigma of 40%. In one or more embodiments, the thickness varies less than 1-sigma of 20%, 10%, 5%, 1%, or 0.1%. The protective coatings provide corrosion and oxidation protection when the aerospace components are exposed to air, oxygen, sulfur and/or sulfur compounds, acids, bases, salts (e.g., Na, K, Mg, Li, or Ca salts), or any combination thereof.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. An aerospace component containing a protective coating, comprising:
a nickel-based superalloy substrate;
a bond coating disposed on the nickel-based superalloy substrate, wherein the bond coating comprises an alloy containing chromium and aluminum;
a thermal barrier coating comprising yttria-stabilized zirconia disposed on the bond coating; and
an oxide coating disposed on the thermal barrier coating.

2. The aerospace component of claim 1, wherein the oxide coating comprises aluminum oxide, gadolinium oxide, calcium oxide, titanium oxide, magnesium oxide, dopants thereof, or any combination thereof.

3. The aerospace component of claim 1, wherein the oxide coating comprises aluminum gadolinium oxide, lanthanum cerium oxide, lanthanum zirconium oxide, rhenium aluminum oxide, rhenium zirconium oxide, rhenium hafnium oxide, dopants thereof, or any combination thereof.

4. The aerospace component of claim 1, wherein the oxide coating is a film comprising a mixture of aluminum oxide and gadolinium oxide, a mixture of calcium oxide and gadolinium oxide, a mixture of aluminum oxide and titanium oxide, a mixture of gadolinium oxide and magnesium oxide, dopants thereof, or any combination thereof.

5. The aerospace component of claim 1, wherein the oxide coating comprises a first film disposed on the thermal barrier coating and a second film disposed on the first film, and wherein the first film comprises a first metal oxide and the second film comprises a second metal oxide, and the first metal oxide has a different composition than the second metal oxide.

6. The aerospace component of claim 5, wherein:
the first film comprises gadolinium oxide and the second film comprises aluminum oxide;
the first film comprises a mixture of aluminum oxide and gadolinium oxide and the second film comprises aluminum oxide;
the first film comprises gadolinium oxide and the second film comprises calcium oxide;
the first film comprises a mixture of calcium oxide and gadolinium oxide and the second film comprises calcium oxide;
the first film comprises a mixture of calcium oxide and gadolinium oxide and the second film comprises aluminum oxide;
the first film comprises gadolinium oxide and the second film comprises titanium oxide;
the first film comprises a mixture of titanium oxide and gadolinium oxide and the second film comprises titanium oxide;
the first film comprises a mixture of titanium oxide and gadolinium oxide and the second film comprises aluminum oxide;
the first film comprises a mixture of titanium oxide and gadolinium oxide and the second film comprises calcium oxide;
the first film comprises gadolinium oxide and the second film comprises magnesium oxide;
the first film comprises a mixture of magnesium oxide and gadolinium oxide and the second film comprises magnesium oxide;
the first film comprises a mixture of magnesium oxide and gadolinium oxide and the second film comprises aluminum oxide; or
the first film comprises a mixture of magnesium oxide and gadolinium oxide and the second film comprises calcium oxide.

7. The aerospace component of claim 5, wherein each of the first film and the second film independently has a thickness of about 1 nm to about 1 μm.

8. The aerospace component of claim 1, wherein the oxide coating comprises:
a film stack containing two or more pairs of a first film and a second film, wherein the first film comprises a first metal oxide and the second film comprises a second metal oxide, and the first metal oxide has a different composition than the second metal oxide; and
a capping layer disposed on the film stack, wherein the capping layer comprises aluminum oxide, calcium oxide, magnesium oxide, or any combination thereof.

9. The aerospace component of claim 8, wherein:
the first film comprises aluminum oxide, calcium oxide, magnesium oxide, titanium oxide, zinc oxide, or any combination thereof;
the second film comprises gadolinium oxide; and
the second film is disposed on the first film.

10. The aerospace component of claim 8, wherein each of the first film and the second film independently has a thickness of about 1 nm to about 1 μm.

11. The aerospace component of claim 1, wherein the alloy of the bond coating further comprises a first element selected from nickel or cobalt and a second element selected from hafnium, tungsten, zirconium, yttrium, or lanthanide.

12. The aerospace component of claim 11, wherein the alloy of the bond coating has the formula MCrAlX, where M is nickel or cobalt and X is hafnium, tungsten, zirconium, yttrium, or lanthanide.

13. The aerospace component of claim 1, wherein the yttria-stabilized zirconia of the thermal barrier coating comprises about 5 molar percent (mol %) to about 10 mol % of yttria and about 90 mol % to about 95 mol % of zirconia.

14. The aerospace component of claim 1, wherein the oxide coating has a thickness of about 10 nm to about 10 μm, and wherein the bond coating has a thickness of about 100 nm to about 50 μm.

15. The aerospace component of claim 1, the nickel-based superalloy substrate is a turbine blade, a turbine disk, a turbine vane, a turbine wheel, a fan blade, a compressor wheel, an impeller, a fuel nozzle, a fuel line, a valve, a heat exchanger, or an internal cooling channel.

16. An aerospace component containing a protective coating, comprising:
a nickel-based superalloy substrate;
a bond coating disposed on the nickel-based superalloy substrate, wherein the bond coating comprises an alloy containing chromium, aluminum, a first element selected from nickel or cobalt, and a second element selected from hafnium, tungsten, zirconium, yttrium, or lanthanide;
a thermal barrier coating comprising yttria-stabilized zirconia disposed on the bond coating;
an oxide coating disposed on the thermal barrier coating, wherein the oxide coating comprises a film stack containing two or more pairs of a first film and a second film, and wherein the first film comprises a first metal oxide and the second film comprises a second metal oxide, and the first metal oxide has a different composition than the second metal oxide; and
a capping layer disposed on the oxide coating, wherein the capping layer comprises aluminum oxide, calcium oxide, magnesium oxide, or any combination thereof.

17. A method of forming a protective coating on an aerospace component, comprising:
depositing a bond coating on a nickel-based superalloy substrate, wherein the bond coating comprises an alloy containing chromium, aluminum, a first element selected from nickel or cobalt, and a second element selected from hafnium, tungsten, zirconium, yttrium, or lanthanide;
depositing a thermal barrier coating comprising yttria-stabilized zirconia on the bond coating; and
forming an oxide coating on the thermal barrier coating by depositing a film stack containing a first film and a second film by atomic layer deposition, wherein the first film comprises a first metal oxide and the second film comprises a second metal oxide, and the first metal oxide has a different composition than the second metal oxide.

18. The method of claim 17, wherein:
the first film comprises gadolinium oxide and the second film comprises aluminum oxide;
the first film comprises a mixture of aluminum oxide and gadolinium oxide and the second film comprises aluminum oxide;
the first film comprises gadolinium oxide and the second film comprises calcium oxide;
the first film comprises a mixture of calcium oxide and gadolinium oxide and the second film comprises calcium oxide;
the first film comprises a mixture of calcium oxide and gadolinium oxide and the second film comprises aluminum oxide;
the first film comprises gadolinium oxide and the second film comprises titanium oxide;
the first film comprises a mixture of titanium oxide and gadolinium oxide and the second film comprises titanium oxide;
the first film comprises a mixture of titanium oxide and gadolinium oxide and the second film comprises aluminum oxide;
the first film comprises a mixture of titanium oxide and gadolinium oxide and the second film comprises calcium oxide;
the first film comprises gadolinium oxide and the second film comprises magnesium oxide;
the first film comprises a mixture of magnesium oxide and gadolinium oxide and the second film comprises magnesium oxide;
the first film comprises a mixture of magnesium oxide and gadolinium oxide and the second film comprises aluminum oxide; or
the first film comprises a mixture of magnesium oxide and gadolinium oxide and the second film comprises calcium oxide.

19. The method of claim 17, wherein:
the first film comprises aluminum oxide, calcium oxide, magnesium oxide, titanium oxide, zinc oxide, or any combination thereof;
the second film comprises gadolinium oxide; and
the second film is deposited on the first film.

20. The method of claim 17, further comprising depositing a capping layer on the oxide coating, wherein the capping layer comprises aluminum oxide, calcium oxide, magnesium oxide, or any combination thereof.
